(19) United States
(12) Patent Application Publication
(10) Pub. No.: US 2025/0293167 A1
(43) Pub. Date: Sep. 18, 2025

(54) THREE-DIMENSIONAL STRUCTURE BOARD

(71) Applicant: AISIN CORPORATION, Kariya (JP)

(72) Inventors: Tomoya FUJIOKA, Kariya-shi (JP); Satoshi Nakagaki, Kariya-shi (JP)

(73) Assignee: AISIN CORPORATION, Kariya (JP)

(21) Appl. No.: 19/057,144

(22) Filed: Feb. 19, 2025

(30) Foreign Application Priority Data
Mar. 14, 2024 (JP) 2024-040130

(51) Int. Cl. H01L 23/538; H01L 23/367; H01L 25/18

(52) U.S. Cl. CPC H01L 23/5385; H01L 23/367; H01L 23/5387; H01L 25/18

(57) ABSTRACT

A three-dimensional structure board having high heat dissipation efficiency includes a plurality of substrates on each of which at least one electronic component is mounted; and a connecting part that provides connection between a plurality of the substrates in an elastically deformable manner, and includes a circuit pattern to be electrically connected to each of the electronic components, wherein the connecting part provides connection between a plurality of the substrates in a three-dimensional manner with the circuit pattern exposed to an outside.

### CROSS REFERENCE TO RELATED APPLICATIONS

This application is based on and claims priority under 35 U.S.C. § 119 to Japanese Patent Application 2024-040130, filed on Mar. 14, 2024, the entire content of which is incorporated herein by reference.

### TECHNICAL FIELD

This disclosure generally relates to a three-dimensional structure board having a plurality of electronic components mounted thereon in a three-dimensional manner.

### BACKGROUND DISCUSSION

In recent years, automobiles equipped with an electric motor as a driving source have been widespread, such as a hybrid electric vehicle (HEV), a plug-in hybrid electric vehicle (PHEV), a battery electric vehicle (BEV), and a fuel cell electric vehicle (FCEV). Hereinafter, such automobiles are collectively referred to as an electric vehicle. The electric vehicle includes many devices that require cooling, such as a motor (including an internal-combustion engine such as an engine), a battery, an air conditioner, and an ECU, and thus, in order to reduce a space for mounting a circuit board, there has been developed a three-dimensional structure board having a plurality of electronic components mounted thereon in a three-dimensional manner. While the three-dimensional structure board enables space for mounting the board to be reduced, a plurality of electronic components are disposed opposite to one another, and thus, heat dissipation efficiency needs to be enhanced.

A circuit board described in JP2003-069171A includes resist film provided on copper foil that forms a circuit pattern, and solder is applied on regions other than the resist film. Since the solder is applied on the regions other than the resist film, heat generated by electronic components is dissipated from a surface of the solder.

When the heat generated by the electronic components is dissipated from the surface of the solder as in the circuit board described in JP2003-006971A, thermal conductivity of the solder also acts as thermal resistance, leading to a problem of heat dissipation efficiency being reduced. Particularly, application of the technique described in JP2003-006971A to a three-dimensional structure board is not good enough in terms of heat dissipation, and the heat dissipation efficiency needs to be further enhanced.

A need thus exists for a three-dimensional structure board, which is not susceptible to the drawback mentioned above.

### SUMMARY

A three-dimensional structure board according to this disclosure includes a plurality of substrates on each of which at least one electronic component is mounted; and a connecting part that provides connection between a plurality of the substrates in an elastically deformable manner, and includes a circuit pattern to be electrically connected to each of the electronic components, wherein the connecting part includes an area where the circuit pattern is exposed to an outside and provides connection between a plurality of the substrates in a three-dimensional manner.

### BRIEF DESCRIPTION OF THE DRAWINGS

The foregoing and additional features and characteristics of this disclosure will become more apparent from the following detailed description considered with the reference to the accompanying drawings, wherein:

FIG. 1 is a perspective view illustrating a three-dimensional structure board in entirety;

FIG. 2 schematically illustrates electronic components, exposed connecting patterns, and the like in the three-dimensional structure board;

FIG. 3 is an enlarged sectional view of the three-dimensional structure board;

FIG. 4 is a perspective view illustrating the three-dimensional structure board in a tubular form and an access board; and

FIG. 5 is a cross-sectional view of the three-dimensional structure board in the tubular form.

### DETAILED DESCRIPTION

Embodiments of a three-dimensional structure board according to this disclosure are described below based on the drawings. The three-dimensional structure board according to this disclosure is not restricted by the embodiments to be described below, and various variations may be made without departing from the spirit and the scope of this disclosure.

### (Basic Configuration)

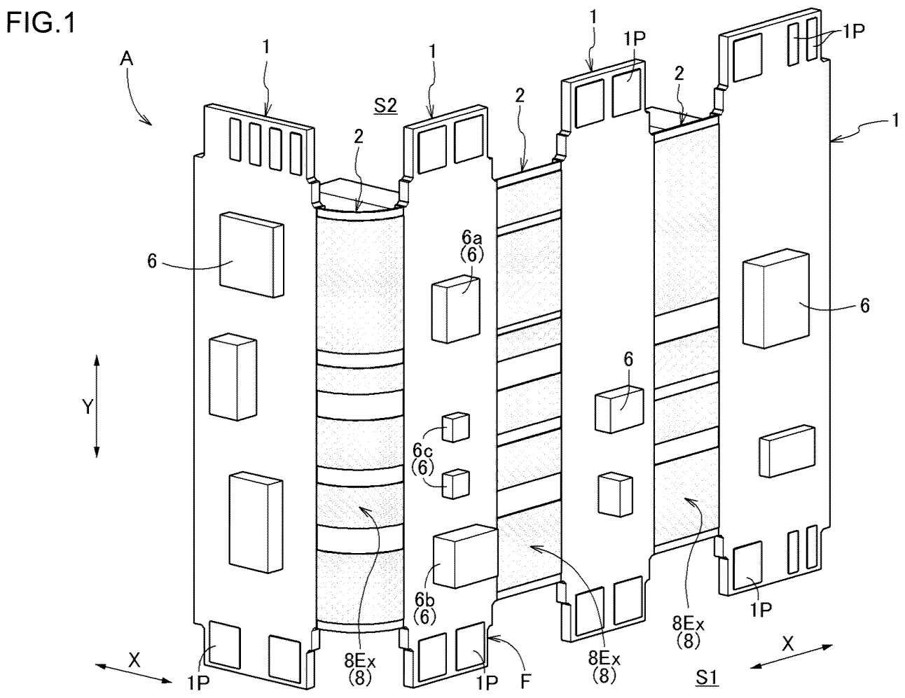

As illustrated in FIG. 1, a three-dimensional structure board A is constructed by connecting plate-shaped rigid parts 1 (an example of a substrate) that is hardly deformable and flexible parts 2 (an example of a connecting part) in such a way as to be electrically connected with each other.

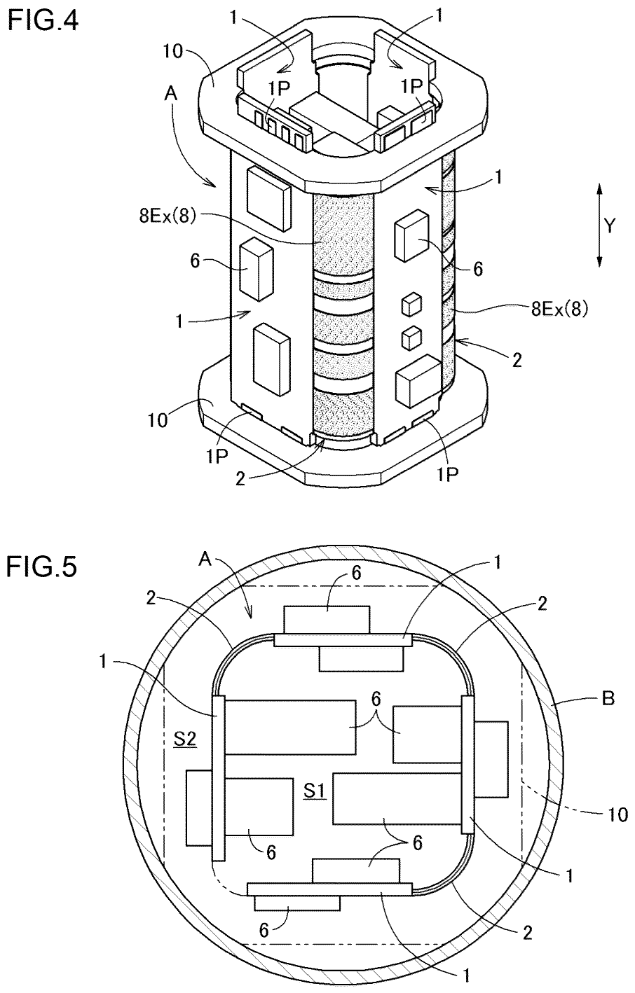

As illustrated in FIG. 4 and FIG. 5, the three-dimensional structure board A is constructed in such a way that the board can be housed in a tubular case B by bending a plurality of the flexible parts 2 (connecting parts) and disposing a plurality of the rigid parts 1 (substrates) inside an annular region when viewed along a longitudinal direction Y. The three-dimensional structure board A is used in a vertical orientation as illustrated in FIG. 4.

### (Rigid Part/Flexible Part 2)

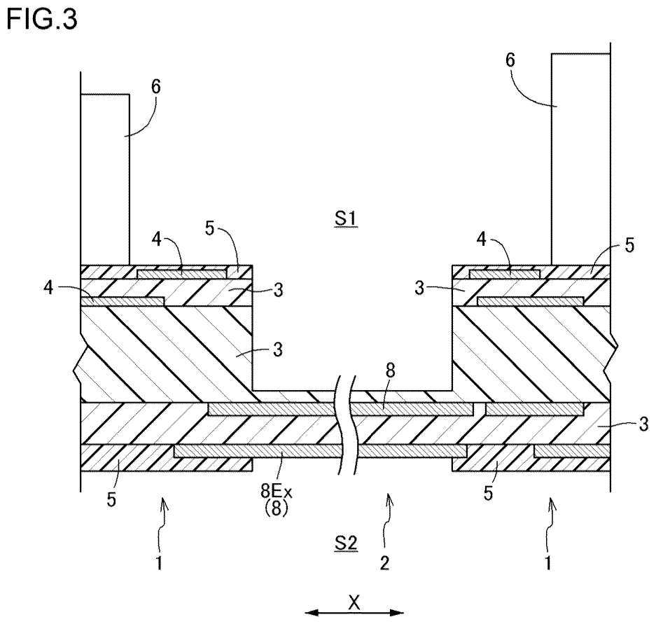

As illustrated in FIG. 3, in the rigid part 1 (substrate), a plurality of wiring patterns 4 made of copper foil are formed on a plurality of insulating layers 3 made from a glass epoxy resin or the like, and resist film 5 made from an insulating resin material is formed for coating the wiring patterns 4 located on an inner side S1 and an outer side S2.

The rigid part 1 has a plurality of electronic components 6 mounted thereon, and these electronic components 6 are electrically connected to the wiring patterns 4.

As illustrated in FIG. 3, the flexible part 2 (connecting part) includes a region having reduced thickness that communicates with the insulating layer 3 of the rigid part 1 and is configured to flexibly and elastically deform thanks to the region. In this flexible part 2, a plurality of connecting patterns 8 made of copper foil are formed, and the flexible part 2 includes an area where one or more of these connecting patterns 8 that are formed on the outer side S2 are exposed.

In other words, one or more of the connecting patterns 8 that are formed on the outer side S2 are not provided with the resist film 5 and the copper foil is exposed, resulting in formation of an exposed connecting pattern 8Ex. This exposed connecting pattern 8Ex causes heat from the pattern to be in contact with air, which enables the heat to be dissipated by contact with air and radiation.

Although, in the present embodiment, the flexible part 2 (connecting part) is constructed by extending the insulating layer 3 of the rigid part 1 toward the outside and reducing thickness of the extended portion of the insulating layer 3, a flexible material different from that of the insulating layer 3 of the rigid part 1 (such as polyimide or polyester film) may be used instead for the flexible part 2 and the flexible part 2 (connecting part) may be constructed by forming the exposed connecting pattern 8Ex on the outer side S2.

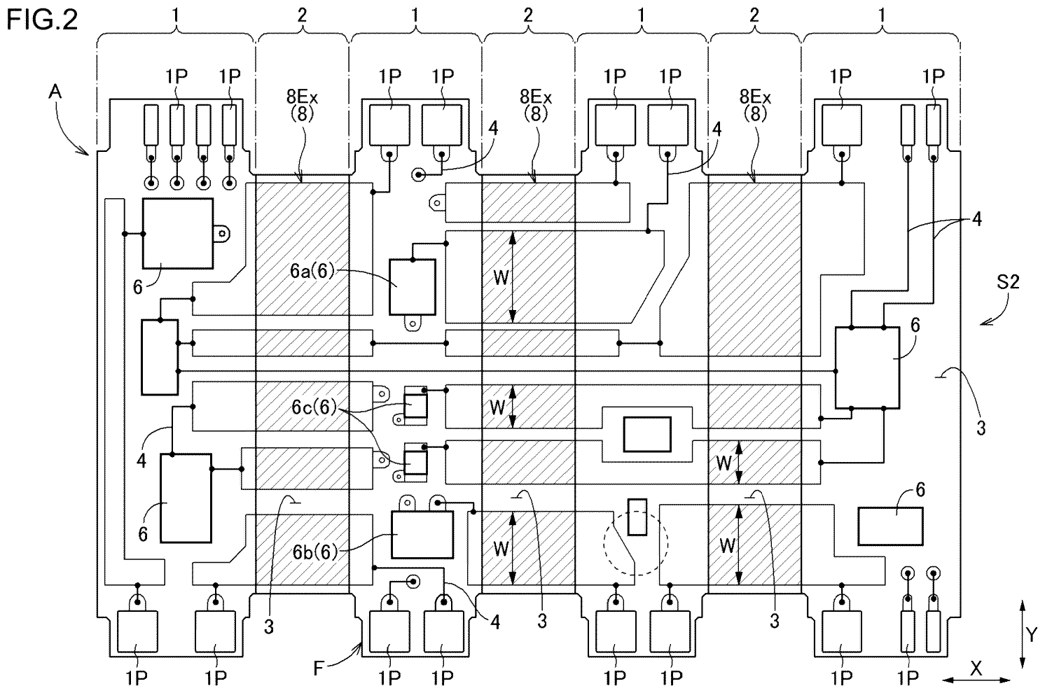

As illustrated in FIG. 1 and FIG. 2, the three-dimensional structure board A includes a plurality of the rigid parts 1 (substrates), four of them in the present embodiment, and a plurality of the flexible parts 2, three of them in the present embodiment, and is constructed by bending a plurality of the flexible parts 2.

The rigid parts 1 are strip-shaped with a size in the longitudinal direction Y bigger than that in a width direction X perpendicular thereto. The flexible part 2 is disposed between the rigid parts 1 and a size of the flexible part 2 in the longitudinal direction Y is slightly shorter than that of the rigid part 1 in the longitudinal direction Y.

In the three-dimensional structure board A, the flexible parts 2 are bent and the rigid parts 1 and the flexible parts 2 are arranged to make a tubular form. In order to keep this arrangement, a pair of access boards 10 are provided and engage with both ends of the rigid parts 1 in the longitudinal direction Y (also see FIG. 4).

As illustrated in FIG. 4 and FIG. 5, electrode pads 1P for external connection are formed at both ends of the rigid parts 1 in the longitudinal direction Y on the outer side S2. By electrically connecting these electrode pads 1P with an electrode on the access board 10 (not illustrated), supply of electrical power via the access board 10 and transmission of a control signal are achieved.

The three-dimensional structure board A is assumed to be housed in the tubular case B into which part of a brushless DC motor (not illustrated) is fit since the three-dimensional structure board A controls electric current to be supplied to the brushless DC motor.

### (Arrangement of Electronic Components)

The three-dimensional structure board A is used in an orientation in which a longitudinal direction of the rigid parts 1 coincides with the longitudinal direction Y as illustrated in FIG. 1 and FIG. 2. In this orientation, relative positional relationship among electronic components 6 mounted on the rigid parts 1 are configured in such a way as to reduce an effect of heat generated by the electronic components 6 on other electronic components 6.

FIG. 2 schematically illustrates arrangement of the electronic components 6, the connecting patterns 8, and the like. As illustrated in FIG. 2, one of the rigid parts 1 (substrates) is referred to as a first substrate F for which arrangement of the electronic components 6 is considered. In the first substrate F, a first electronic component 6a that generates relatively more heat, such as a Power MOSFET or an IGBT, is disposed on an upper side, a second electronic component 6b having relatively low heat resistance is disposed on a lower side, and a third electronic component 6c that generates less heat than the first electronic component 6a and that is more heat-resistant than the second electronic component 6b is disposed between the first electronic component 6a and the second electronic component 6b in the vertical direction.

Note that the first electronic component 6a, the second electronic component 6b, and the third electronic component 6c fall into the concept of electronic components 6, and any of the electronic components 6 mounted on the rigid parts 1 (substrates) other than the first substrate F possess a nature of either the first electronic component 6a, the second electronic component 6b, or the third electronic component 6c.

The three-dimensional structure board A increases a distance between the first electronic component 6a and the second electronic component 6b in the vertical direction and reduces an effect of heat due to heat conduction on the first substrate F with arrangement of the electronic components 6 as described for the first substrate F. The three-dimensional structure board A also reduces an amount of heat due to convection of air that affects the second electronic component 6b since the first electronic component 6a is disposed on the upper side of the first substrate F.

This arrangement of the electronic components 6 may enhance durability of the electronic component 6 having low heat resistance (third electronic component 6c).

### (Heat-Dissipating Structure)

The rigid part 1 is provided with, as illustrated in FIG. 3, a plurality of layers of the wiring patterns 4 with the insulating layer 3 therebetween. Similarly to this, the flexible part 2 is provided with a plurality of layers of the connecting patterns 8 with the insulating layer 3 therebetween.

The one on the inner side S1 of the wiring patterns 4 is electrically connected with the one on the inner side S1 of the connecting patterns 8. The one on the outer side S2 of the wiring patterns 4 is electrically connected with the one on the outer side S2 of the connecting patterns 8.

As described above, in the three-dimensional structure board A, the exposed connecting pattern 8Ex is exposed on the outer side S2 of the insulating layer 3 of the flexible part 2.

Among the electronic components 6, one that controls large electrical power, such as a Power MOSFET or an IGBT, as described above, generates large amount of heat. Even the electronic component 6 that does not control large electric current generates heat when operating (energized).

Heat generated by these electric components 6 not only causes temperature of the rigid part 1 to increase but also causes overall temperature of the three-dimensional structure board A to increase. For these reasons, positional relationship between the wiring patterns 4 is configured in such a way that a control signal for controlling the electronic components 6 is transmitted via the pattern on the inner side S1 of the layers of the wiring patterns 4 and electric current to be controlled by the electronic components 6 passes through the pattern on the outer side S2 of the layers of the wiring patterns 4.

As schematically illustrated in FIG. 2, the exposed connecting pattern 8Ex of the connecting patterns 8 that is not coated with the resist film 5 and that is exposed to the outer side S2 is formed with a large pattern width W (a width in the longitudinal direction Y). The exposed connecting pattern 8Ex is formed in a region indicated by hatching in FIG. 2.

In the present embodiment, the pattern width W of the exposed connecting pattern 8Ex to be connected to the first electronic component 6a, the pattern width W of the exposed connecting pattern 8Ex to be connected to the second electronic component 6b, and the pattern width W of the exposed connecting pattern 8Ex to be connected to the third electronic component 6c are configured to be reduced in this order. It should be noted that relationship among the pattern widths W is not limited to the one described above.

For patterns for which copper foil having a predetermined thickness is used, a reference width is defined in advance based on a relation between a value of electric current and a pattern width. The wiring pattern 4 formed in the rigid part 1 illustrated in FIG. 4 is formed as a pattern having a width conforming to the reference width. In contrast, the exposed connecting pattern 8Ex is formed with a large pattern width W (the width in the longitudinal direction Y) exceeding the reference width.

Thus, the exposed connecting pattern 8Ex enables good heat dissipation since the copper foil is exposed (in other words, the pattern is not coated with the resist film 5). As a result, heat generated by the electronic components 6 on the rigid part 1 is dissipated by the exposed connecting pattern 8Ex on the outer side S2 of the flexible part 2, achieving reduction in overall temperature of the three-dimensional structure board A.

### (Advantageous Effects of the Present Embodiment)

Thus, by electrically connecting a plurality of substrates (rigid parts 1) on which the electronic components 6 are mounted with the flexible parts 2 (connecting part) on which no electronic component 6 is mounted, the three-dimensional structure board A may enable three-dimensional positions of the rigid parts 1 to be changed by bending the flexible parts 2. In addition, since the three-dimensional structure board A has a three-dimensional structure, the three-dimensional structure board A may be housed in an interior space of the tubular case B.

In the three-dimensional structure board A, the exposed connecting pattern 8Ex is formed by exposing the copper foil of the connecting pattern 8 formed in the flexible part 2, and the exposed connecting pattern 8Ex does not have an effect of thermal resistance of the resist film 5 compared to a configuration in which the resist film 5 is formed on the outer side S2 of the connecting pattern 8, thus enabling heat generated by the electronic components 6 to be dissipated from a wide surface.

In addition, in the three-dimensional structure board A, the pattern width of the copper foil of the connecting pattern 8 is set to the pattern width W greater than the reference width, thereby enlarging a heat-dissipating surface. This enhances efficiency of dissipating heat from the copper foil, reduces increase in temperature of the electronic components 6, and improves durability.

By configuring a distance between the first electronic component 6a that generates more heat and the second electronic component 6b having relatively low heat resistance, among the electronic components 6 mounted on the rigid part 1 (substrate) to be long and disposing the first electronic component 6a on the upper side of the rigid part 1, durability of the electronic component 6 having low heat resistance (third electronic component 6c) is enhanced.

### Alternative Embodiment

This disclosure may be implemented not only as in the embodiment described above, but with a configuration to be described below (note that a component having the same function as that in the embodiment described above is assigned with the same reference numeral or sign).
(a) As partially described in the foregoing embodiment, the three-dimensional structure board A may be integrally formed of the rigid part 1 and the flexible part 2, both of which are made from the same material, or constructed from the rigid part 1 and the flexible part 2 that are made from different materials.

Alternatively, in the three-dimensional structure board A, part of the flexible parts 2 may be made from the same material as and integrally formed with the rigid part 1 while other part of the flexible part 2 may be formed from a material different from that of the rigid part 1. In addition, an area for exposing the circuit pattern of the flexible part 2 (connecting part) may be only a part of the flexible part 2.
(b) Although in the embodiment described above, the access board 10 is employed, the three-dimensional structure board A may be configured without using the access board 10.
(c) The shapes and the numbers of the rigid parts 1 and the flexible parts 2 may be configured as desired according to an object to be controlled or a size of a space for accommodating the three-dimensional structure board A.

Note that the configurations disclosed in the embodiments described above (including the alternative embodiments, which also applies in the following) may be combined with the configuration disclosed in another embodiment and that the embodiments disclosed in the present description are merely exemplary and embodiments of this disclosure are not limited to those embodiments, and modifications may be appropriately made to those embodiments without departing from the purpose of this disclosure.

### INDUSTRIAL APPLICABILITY

This disclosure may be used for a three-dimensional structure board.

In the embodiments that have been described above, configurations to be described below are conceived.
(1) The three-dimensional structure board includes a plurality of substrates (rigid parts 1), on each of which at least one electronic component 6 is mounted; and a connecting part (flexible part 2) that provides connection between a plurality of the substrates (rigid parts 1) in an elastically deformable manner, the connecting part including a circuit pattern (connecting pattern 8) to be electrically connected to each of the electronic components 6, wherein the connecting part (flexible part 2) includes an area where the circuit pattern (connecting pattern 8) is exposed to an outside and provides connection between a plurality of the substrates (rigid parts 1) in a three-dimensional manner.

In the present configuration, among the circuit patterns to be electrically connected to each of the electronic components 6, the circuit pattern (connecting pattern 8) in the connecting part (flexible part 2) is exposed to an outside. Therefore, because of the circuit pattern having lower thermal resistance than solder, heat dissipation efficiency of dissipating heat generated by the electronic components 6 can be enhanced.

The circuit pattern (connecting pattern 8), in particular, that is provided in the elastically deformable and curved connecting part as in the present configuration can work without resist film 5 to be used for preventing shorting of solder and can serve a radiative cooling function by being exposed to an outside. Thus, the three-dimensional structure board A has high heat dissipation efficiency.
(2) In the three-dimensional structure board A according to (1), the circuit pattern (connecting pattern 8) of the connecting part (flexible part 2) may have a pattern width W that is greater than a reference width required for an electric connection with each of the electronic components 6.

By configuring the pattern width W of the circuit pattern (connecting pattern 8) of the connecting part (flexible part 2) to be greater than the reference width as in the present configuration, an unused space of the connecting part (flexible part 2) may be effectively utilized and the heat dissipation efficiency may be further enhanced.
(3) In the three-dimensional structure board according to (1) or (2), the pattern width of the circuit pattern (connecting pattern 8) of the connecting part (flexible part 2) to be connected to the electronic component 6 that generates relatively more heat may be greater than that of the circuit pattern to be connected to another one of the electronic components 6.

By configuring the pattern width W of the circuit pattern (connecting pattern 8) to be connected to the electronic component 6 that generates relatively more heat to be wide as in the present configuration, the heat dissipation efficiency may be effectively enhanced.
(4) In the three-dimensional structure board A according to any one of (1) to (3), the substrate (rigid part 1) includes a first substrate F on which at least three of the electronic components 6 are mounted, and on the first substrate F between the electronic component 6 (first electronic component 6a) that generates relatively more heat and the electronic component 6 (second electronic component 6b) having relatively low heat resistance, another one (third electronic component 6c) of the electronic components 6 may be disposed.

By disposing the electronic component 6 (first electronic component 6a) that generates relatively more heat spaced apart from the electronic component 6 (second electronic component 6b) having relatively low heat resistance as in this configuration, durability of the electronic components 6 may be enhanced. In addition, another one of the electronic components 6 prevents heat generated by the electronic component 6 that generates relatively more heat from being transmitted to the electronic component 6 having low heat resistance (second electronic component 6b), thereby enabling durability of the second electronic component 6b to be enhanced.

A three-dimensional structure board according to this disclosure includes a plurality of substrates on each of which at least one electronic component is mounted; and a connecting part that provides connection between a plurality of the substrates in an elastically deformable manner, and includes a circuit pattern to be electrically connected to each of the electronic components, wherein the connecting part includes an area where the circuit pattern is exposed to an outside and provides connection between a plurality of the substrates in a three-dimensional manner.

In the present configuration, among the circuit patterns to be electrically connected to each of the electronic components, the circuit pattern in the connecting part is exposed to an outside. Therefore, because of the circuit pattern having lower thermal resistance than solder, heat dissipation efficiency of dissipating heat generated by the electronic components can be enhanced.

The circuit pattern, in particular, that is provided in the elastically deformable connecting part as in the present configuration can work without resist film to be used for preventing shorting of solder and can serve a radiative cooling function by being exposed to an outside. Thus, the three-dimensional structure board has high heat dissipation efficiency.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

1. A three-dimensional structure board comprising:
a plurality of substrates on each of which at least one electronic component is mounted; and
a connecting part that provides connection between a plurality of the substrates in an elastically deformable manner, and includes a circuit pattern to be electrically connected to each of the electronic components, wherein
the connecting part includes an area where the circuit pattern is exposed to an outside and provides connection between a plurality of the substrates in a three-dimensional manner.

2. The three-dimensional structure board according to claim 1, wherein the circuit pattern of the connecting part has a pattern width being greater than a reference width required for electric connection with each of the electronic components.

3. The three-dimensional structure board according to claim 2, wherein the pattern width of the circuit pattern of the connecting part to be connected to the electronic component that generates relatively more heat is greater than that of the circuit pattern to be connected to another of the electronic components.

4. The three-dimensional structure board according to claim 1, wherein
the substrates include a first substrate on which at least three of the electronic components are mounted, and,
on the first substrate between the electronic component that generates relatively more heat and the electronic component having relatively low heat resistance, another of the electronic components is disposed.

5. The three-dimensional structure board according to claim 2, wherein
the substrates include a first substrate on which at least three of the electronic components are mounted, and,
on the first substrate between the electronic component that generates relatively more heat and the electronic component having relatively low heat resistance, another of the electronic components is disposed.

6. The three-dimensional structure board according to claim 3, wherein
the substrates include a first substrate on which at least three of the electronic components are mounted, and,
on the first substrate between the electronic component that generates relatively more heat and the electronic component having relatively low heat resistance, another of the electronic components is disposed.
